(19) United States
(12) Patent Application Publication
(10) Pub. No.: US 2024/0399494 A1
(43) Pub. Date: Dec. 5, 2024

(54) WAFER PROCESSING METHOD AND CHAMFER REMOVING APPARATUS

(71) Applicant: DISCO CORPORATION, Tokyo (JP)

(72) Inventors: Kazuya HIRATA, Tokyo (JP); Hayato IGA, Tokyo (JP); Hayato TANAKA, Tokyo (JP); Akira MIZUTANI, Tokyo (JP)

(21) Appl. No.: 18/676,817

(22) Filed: May 29, 2024

(30) Foreign Application Priority Data
May 30, 2023 (JP) 2023-088747

(51) Int. Cl. B23K 26/00; B23K 26/38; B23K 26/53; B23K 101/40

(52) U.S. Cl. CPC B23K 26/0093; B23K 26/38; B23K 26/53; B23K 2101/40

(57) ABSTRACT

A wafer processing method for processing a wafer that has an effective region and a chamfer at an end part of a periphery surrounding the effective region includes a modified layer forming step of applying a laser beam of such a wavelength as to be transmitted through the wafer, with a focal point of the laser beam positioned in the inside of a boundary part between the effective region and the chamfer, to thereby form a modified layer along the chamfer, a chamfer removing step of holding the effective region of the wafer and exerting an external force on the periphery of the wafer to thereby remove the chamfer, and a processing step of grinding a back surface of the wafer from which the chamfer has been removed, to thereby process the wafer to a desired thickness.

### BACKGROUND OF THE INVENTION

### Field of the Invention

The present invention relates to a wafer processing method for processing a wafer that has an effective region and a chamfer at an end part of a periphery surrounding the effective region and a chamfer removing apparatus.

### Description of the Related Art

A wafer formed on its front surface with a device region in which a plurality of devices such as integrated circuits (ICs) and large scale integration (LSI) circuits are partitioned by a plurality of intersecting streets has its back surface ground and processed to a desired thickness, and is thereafter divided into individual device chips by a cutting apparatus or a laser processing apparatus, and the thus divided device chips are utilized for electric apparatuses such as mobile phones and personal computers.

A chamfer is formed at the periphery of the wafer, and, when the back surface of the wafer is ground to thin the wafer, the chamfer becomes sharp like a knife edge, causing such a problem that the operator is injured or that cracks are generated from the periphery of the wafer to damage the devices.

In view of this, a technology in which, before grinding the back surface of the wafer, a laser beam of such a wavelength as to be transmitted through the wafer is applied to the wafer, with a focal point of the laser beam positioned in the inside of the chamfer, to form an annular modified layer in the inside of the wafer, whereby the chamfer is removed at the time of grinding has been proposed by the present applicant (see Japanese Patent Laid-open No. 2020-088187).

### SUMMARY OF THE INVENTION

According to the technology disclosed in Japanese Patent Laid-open No. 2020-088187, the chamfer is removed by an external force exerted during grinding, and there is such a problem that fragments of the chamfer dropping off from the wafer would stagnate in a drain pan into which grinding water containing grinding swarf generated during grinding is discharged, making it necessary to frequently clean the inside of the drain pan, which is very troublesome.

Accordingly, it is an object of the present invention to provide a wafer processing method and a chamfer removing apparatus by which it is possible to effectively remove a chamfer from the periphery of a wafer before carrying out grinding by a grinding apparatus.

In accordance with an aspect of the present invention, there is provided a wafer processing method for processing a wafer that has an effective region and a chamfer at an end part of a periphery surrounding the effective region, the wafer processing method including a modified layer forming step of applying a laser beam of such a wavelength as to be transmitted through the wafer to the wafer, with a focal point of the laser beam positioned in inside of a boundary part between the effective region and the chamfer, to thereby form a modified layer along the chamfer, a chamfer removing step of holding the effective region of the wafer and exerting an external force on the periphery of the wafer to thereby remove the chamfer, and a processing step of grinding a back surface of the wafer from which the chamfer has been removed, to thereby process the wafer to a desired thickness.

Preferably, the external force exerted on the periphery of the wafer in the chamfer removing step is any of high-pressure air, high-pressure water, a mixed fluid of high-pressure air and high-pressure water, and a picker. Preferably, the wafer is a bonded wafer in which a first wafer and a second wafer are bonded with each other, and the modified layer forming step, the chamfer removing step, and the processing step are carried out on the first wafer.

In accordance with another aspect of the present invention, there is provided a chamfer removing apparatus for removing a chamfer from a wafer which has an effective region and the chamfer at an end part of a periphery surrounding the effective region and in which a modified layer has been formed along the chamfer, the chamfer removing apparatus including a holding unit that has a holding surface for holding the effective region of the wafer, and a chamfer removing unit that exerts an external force on the periphery, of the wafer held by the holding unit, the periphery projecting outward from the holding surface, to thereby remove the chamfer from the effective region.

Preferably, the chamfer removing unit is means for exerting an external force on the periphery of the wafer by any of high-pressure air, high-pressure water, a mixed fluid of high-pressure air and high-pressure water, and a picker.

According to the wafer processing method of the present invention, it is possible to effectively remove the chamfer from the periphery of the wafer before grinding the back surface of the wafer to process the wafer to a desired thickness, so that such a problem that the chamfer would stagnate in a drain pan of a grinding apparatus for carrying out the processing step, making it necessary to frequently clean the drain pan, which is very troublesome, is solved.

According to the chamfer removing apparatus of the present invention, it is possible to effectively remove the chamfer from the periphery of the wafer before grinding the back surface of the wafer to process the wafer to a desired thickness, so that such a problem that fragments of the chamfer would stagnate in a drain pan of a grinding apparatus for carrying out the processing step in the wafer processing method described above, making it necessary to frequently clean the drain pan, which is very troublesome, is solved.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view depicting a simple wafer to be processed by a wafer processing method according to the present embodiment;

FIG. 1B is a perspective view of a bonded wafer in which a first wafer and a second wafer are bonded with each other and which is to be processed by the wafer processing method according to the present embodiment;

FIG. 2A is a perspective view depicting a mode in which the wafer depicted in FIG. 1A is held by a chuck table of a laser processing apparatus;

FIG. 2B is a perspective view depicting a mode in which a modified layer is formed in the wafer held by the chuck table;

FIGS. 3A to 3D are enlarged sectional views of a part depicting a form of the modified layer formed by a modified layer forming step;

FIG. 4A is a perspective view depicting a mode in which the wafer is held by a chuck table of a chamfer removing apparatus;

FIG. 4B is a perspective vide depicting a mode in which fluid is jetted by a fluid jet nozzle of the chamfer removing apparatus;

FIG. 5A is a side view depicting, in an enlarged form, a part of the mode depicted in FIG. 4B;

FIG. 5B is a side view depicting, in an enlarged form, a part of the wafer from which a chamfer has been removed;

FIG. 5C is a perspective view of the whole part of the wafer from which the chamfer has been removed over the whole circumference;

FIG. 6 is a perspective view depicting an example in which a picker is disposed as a chamfer removing unit;

FIGS. 7A to 7C are side views depicting, in an enlarged form, a part depicted in the mode in which the chamfer is removed by the picker depicted in FIG. 6;

FIG. 7D is a perspective view of the whole part of the wafer from which the chamfer has been removed over the whole circumference; and

FIG. 8 is a perspective view depicting a mode in which a processing step is carried out.

### DETAILED DESCRIPTION OF THE PREFERRED EMBODIMENT

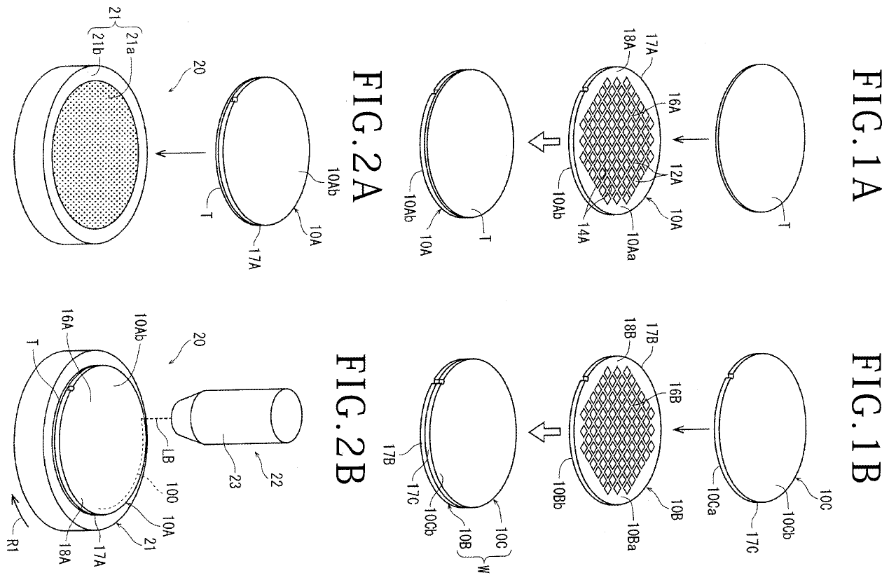

A wafer processing method and a chamfer removing apparatus according to an embodiment of the present invention will be described in detail below with reference to the attached drawings. FIG. 1A illustrates a wafer 10A to be processed by the wafer processing method configured based on the present invention and a protective tape T. The wafer 10A illustrated is, for example, a wafer of silicon having a diameter of 300 mm and a thickness of 700 μm, which is formed on a front surface 10Aa thereof with a plurality of devices 12A being partitioned by a plurality of intersecting streets 14A. The wafer 10A has the front surface 10Aa and a back surface 10Ab, and is formed with a rather central effective region 16A in which the devices 12A to be used as products are formed, a chamfer 17A formed at an end part of a periphery surrounding the effective region 16A, and a boundary part (peripheral surplus region) 18A which is located between the effective region 16A and the chamfer 17A at the periphery and in which the devices 12A to be products are not formed. When the wafer 10A is subjected to processing by the wafer processing method of the present embodiment, the protective tape T is stuck to the front surface 10Aa side of the wafer 10A in an integral manner, as illustrated.

FIG. 1B illustrates another bonded wafer W to be processed by the wafer processing method configured based on the present invention. The bonded wafer W is a bonded wafer formed as one body by bonding a first wafer 10B and a second wafer 10C with each other. The first wafer 10B is, for example, configured in the same way as the above-mentioned wafer 10A, and is a silicon wafer which has a front surface 10Ba and a back surface 10Bb, has a diameter of 300 mm and a thickness of 700 μm, and is formed on the front surface 10Ba thereof with a plurality of devices 12B being partitioned by a plurality of intersecting streets 14B. The first wafer 10B is formed with a rather central effective region 16B in which the devices 12B to be used as products are formed, a chamfer 17B formed at an end part of a periphery surrounding the effective region 16B, and a boundary part 18B which is located between the effective region 16B and the chamfer 17B at the periphery and in which the devices 12B to be products are not formed. The second wafer 10C is also configured in the same way as the first wafer 10B, and, though not illustrated, is a silicon wafer formed on its front surface 10Ca on the lower side in the figure with a plurality of devices being partitioned by streets. The first wafer 10B and the second wafer 10C are formed as one body by bonding the front surface 10Ba of the first wafer 10B and the front surface 10Ca of the second wafer 10C with each other and subjecting the bonded body to heat treatment to thereby achieve lamination through siloxane bonding.

Note that the wafer to be processed by the wafer processing method according to the present embodiment described below is not limited to the above-mentioned simple silicon wafer 10A and the bonded wafer W formed by bonding two silicon wafers, and includes various wafers which each have an effective region and a chamfer at an end part of a periphery surrounding the effective region. For example, the wafer may be a wafer of gallium nitride (GaN), a wafer of gallium arsenide (GaAs), a wafer of lithium tantalate (LiTaO₃), or a wafer of lithium niobate (LiNbO₃), and, further, the wafer may be a wafer in which devices are not formed in a central region but the central region is processed later to be used as products (for example, a glass wafer). In the embodiment to be described below, while the above-mentioned wafer 10A and the bonded wafer W are taken as examples, the wafer processing method and a preferable chamfer removing apparatus according to the present embodiment will be described.

In carrying out the wafer processing method of the present embodiment on the wafer 10A, a modified layer forming step is carried out in which a laser beam of such a wavelength as to be transmitted through the wafer 10A is applied to the wafer 10A, with a focal point of the laser beam positioned in the inside of the boundary part 18A between the effective region 16A and the chamfer 17A, to thereby form a modified layer along the chamfer 17A.

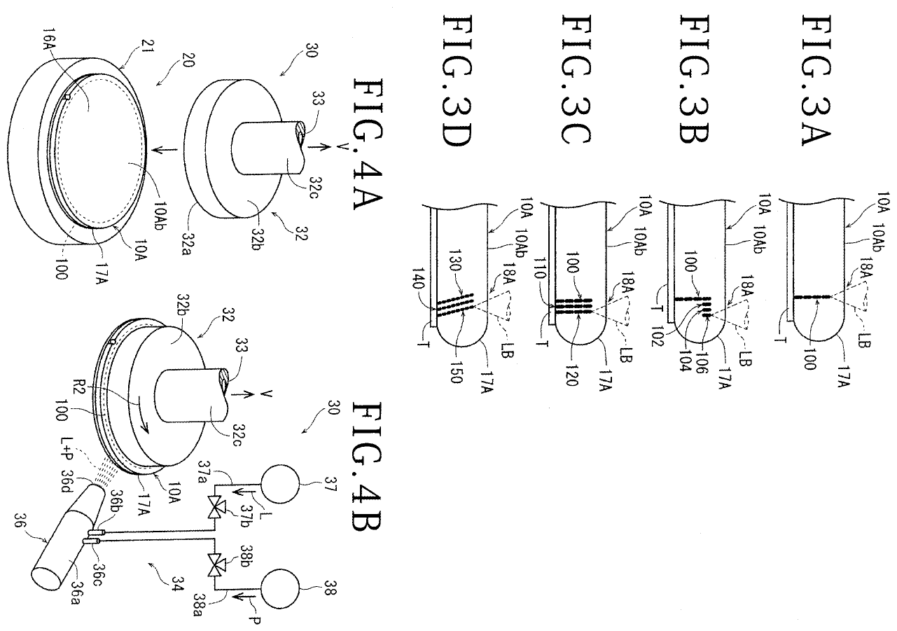

The prepared wafer 10A is conveyed to a laser processing apparatus 20 depicted in FIGS. 2A and 2B (only a part thereof is depicted). The laser processing apparatus 20 includes at least a chuck table 21 depicted in FIG. 2A and a laser beam applying unit 22 depicted in FIG. 2B. The chuck table 21 includes a suction chuck 21a formed of a gas-permeable porous member 21b constituting a holding surface on the upper side and a frame body 21b surrounding the suction chuck 21a. The laser beam applying unit 22 includes a laser oscillator (omitted in illustration) that emits a laser beam LB of such a wavelength as to be transmitted through silicon constituting the wafer 10A and a light concentrator 23 that concentrates the laser beam LB emitted from the laser oscillator and applies the concentrated laser beam LB. The laser processing apparatus 20 further includes a moving mechanism that moves the chuck table 21, a rotational drive mechanism that rotates the chuck table 21, and suction means that generates a negative pressure at an upper surface of the suction chuck 21a (all of them are omitted in illustration).

When the wafer 10A has been conveyed to the laser processing apparatus 20, the wafer 10A is mounted on the chuck table 21 with the protective tape T side directed downward and with the back surface 10Ab side of the wafer 10A directed upward, as depicted in FIG. 2A, and unillustrated suction means is operated to hold the wafer 10A under suction. The wafer 10A held under suction on the chuck table 21 is subjected to alignment by use of an alignment unit and a height detection unit (omitted in illustration) disposed in the laser processing apparatus 20, whereby the position of the end part of the periphery where the chamfer 17A is formed in the wafer 10A and the center position of the wafer 10A are detected, and the height of the upper surface of the back surface 10Ab of the wafer 10A is detected, to thereby detect a processing position of the above-mentioned boundary part 18A to which a laser beam LB is to be applied. By the position of the end part of the periphery where the chamfer 17A is formed in the wafer 10A and the center position of the wafer 10A being detected, for example, a position on the inner side of a region in which the chamfer 17A is formed from the end part of the periphery of the wafer 10A (for example, a region of 0.5 mm from the end part of the periphery) and with a radius of, for example, 147 mm from the center point of the wafer 10A which is set in an annular shape correspondingly to the above-mentioned boundary part 18A is detected as a predetermined processing position. Position information concerning the thus detected processing position is stored in an unillustrated controller.

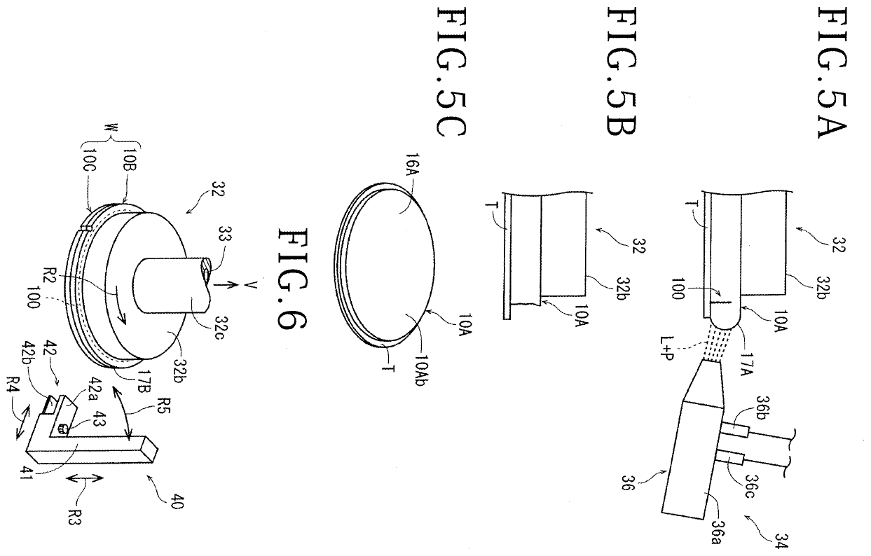

The chuck table 21 is moved in reference to the information concerning the processing position detected by the above-mentioned alignment, and the light concentrator 23 of the laser beam applying unit 22 is positioned to the above-mentioned predetermined processing position, as depicted in FIG. 2B. Next, the laser beam LB is applied to the wafer 10A, with the focal point of the laser beam LB positioned in the inside of the boundary part 18A of the wafer 10A, and the chuck table 21 is rotated in a direction indicated by an arrow R1, to thereby form a modified layer along the chamfer 17A of the wafer 10A over the whole circumference. Note that it is preferable, for enhancing the effect of removal of the chamfer 17A in a chamfer removing step described in detail later, to form the modified layer in the present embodiment not in one layer but in a plurality of layers aligned in the vertical direction. For example, a modified layer 100 depicted in FIG. 3A as one example of the modified layer is a total of four annular modified layers formed by a method in which, at first, the laser beam LB is applied to the wafer 10A, with the focal point of the laser beam LB positioned in a deepest part of the inside of the processing position set in the boundary part 18A, the chuck table 21 is rotated to thereby form the first annular modified layer along the chamfer 17A, and, thereafter, the modified layers are formed along the chamfer 17A by the focal point being raised toward the back surface 10Ab side (upper side) three times. By the above operations, the modified layer forming step is completed.

The laser processing conditions at the time of carrying out the above-described modified layer forming step are set, for example, as follows.
Wavelength: 1,342 nm
Repetition frequency: 60 kHz
Average output: 2.4 W
Rotating speed of chuck table: 107.3 deg/s

Note that the form of the modified layer formed along the chamfer 17A by the modified layer forming step of the present invention is not limited to the form depicted in FIG. 3A. For example, as depicted in FIG. 3B, after the above-mentioned modified layer 100 extending in the vertical direction has been formed, the laser beam LB may be applied, with the focal point of the laser beam LB moved toward the chamfer 17A side (outer side) in the inside of the boundary part 18A a plurality of times, to thereby form annular modified layers 102, 104, and 106 each being a single layer on the back surface 10Ab side along the chamfer 17A. In addition, as depicted in FIG. 3C, after the above-mentioned modified layer 100 has been formed, the laser beam LB may be applied, with the focal point of the laser beam LB moved toward the chamfer 17A side in the inside of the boundary part 18A, to thereby form modified layers 110 and 120 each extending in the vertical direction and including a plurality of layers as the modified layer 100. Further, as depicted in FIG. 3D, after the first modified layer has been formed along the chamfer 17A with the focal point positioned in the deepest part in the inside of the boundary part 18A, a modified layer 130 inclined toward the center side of the wafer 10A may be formed by a method in which the focal point is moved toward the back surface 10Ab side (upper side) of the wafer 10A and the focal point is moved toward the center side of the wafer 10A a plurality of times.

Further, a plurality of modified layers 140 and 150 similar to the modified layer 130 may be formed on the chamfer 17A side (outer side) in parallel to the modified layer 130, as depicted in the figure. Note that, in the case of carrying out the modified layer forming step on the first wafer 10B of the bonded wafer W formed by bonding the first wafer 10B and the second wafer 10C with each other, also, the modified layer or modified layers similar to the modified layer or modified layers depicted in FIGS. 3A to 3D can be formed, by the same procedure as above-described except that the bonded wafer W is held under suction on the chuck table 21 of the laser processing apparatus 20, with the second wafer 10C directed downward, so that detailed description thereof is omitted. In the following description, the description will be continued based on the presumption that the wafer 10A and the first wafer 10B of the bonded wafer W are formed with the modified layer 100 depicted in FIG. 3A by the modified layer forming step.

After the above-described modified layer forming step has been carried out, a chamfer removing step is carried out in which the effective region of the wafer formed with the above-mentioned modified layer is held and an external force is exerted on the periphery of the wafer to thereby remove the chamfer.

FIGS. 4A and 4B illustrate a chamfer removing apparatus 30 (only a part thereof is depicted) preferable for carrying out the chamfer removing step on the wafer 10A having been subjected to the modified layer forming step. The chamfer removing apparatus 30 of the present embodiment includes a holding unit 32 that holds the effective region 16A of the wafer 10A and a fluid jet unit 34 disposed as a chamfer removing unit for removing the chamfer 17A from the effective region 16A of the wafer 10A. The holding unit 32 includes a disk-shaped suction part 32b having a holding surface 32a on the lower side and a support shaft 32c having an unillustrated rotational drive mechanism connected to the center of the suction part 32b. The holding surface 32a is formed of a gas-permeable member, the support shaft 32c is formed therein with a channel 33 that connects unillustrated suction means and the holding surface 32a to each other, and suction is performed through the channel 33 to thereby generate a negative pressure V at the holding surface 32a. The suction part 32b is formed in a size smaller than the size of the wafer 10A and corresponds to the size of the effective region 16A of the wafer 10A.

The fluid jet unit 34 depicted in FIG. 4B is means for removing the chamfer 17A from the effective region 16A by exerting an external force on the periphery of the wafer 10A projecting outward from the holding surface 32a when the effective region 16A is held by the above-mentioned holding unit 32, and the fluid jet unit 34 depicted in the figure includes a fluid jet nozzle 36, a water source 37 that supplies the fluid jet nozzle 36 with high-pressure water L, and an air supply source 38 that supplies the fluid jet nozzle 36 with high-pressure air P. The fluid jet nozzle 36 illustrated is a binary fluid nozzle, the water source 37 is connected to a high-pressure water introduction port 36b formed in a nozzle main body 36a of the fluid jet nozzle 36 through a communication channel 37a including an adjusting valve 37b, and the air supply source 38 is connected to a high-pressure air introduction port 36c formed in the nozzle main body 36b through a communication channel 38a including an adjusting valve 38b. The high-pressure water L introduced into the nozzle main body 36a through the above-mentioned high-pressure water introduction port 36b and the high-pressure air P introduced into the nozzle main body 36a through the high-pressure air introduction port 36c are mixed with each other in the nozzle main body 36a, and the mixed fluid L+P of the high-pressure water L and the high-pressure air P is jetted from a jet port 36d.

In the present embodiment, an example in which the chamfer removing apparatus 30 is juxtaposed to the above-described laser processing apparatus 20 is described, and, as depicted in FIG. 4A, the holding unit 32 is positioned on the chuck table 21 of the laser processing apparatus 20. Next, the holding unit 32 is lowered to be put into contact with the effective region 16A of the wafer 10A, and the unillustrated suction means is operated to apply suction to that region of the back surface 10Ab of the wafer 10A which corresponds to the effective region 16A. Then, the negative pressure generated at the suction chuck 21a of the chuck table 21 is canceled, to hold the wafer 10A on the holding unit 32 side of the chamfer removing apparatus 30. Next, an unillustrated moving mechanism for moving the holding unit 32 is operated, whereby the chamfer 17A formed at the periphery of the wafer 10A is positioned in the vicinity of the jet port 36d of the fluid jet nozzle 36 of the above-described fluid jet unit 34, as illustrated in FIG. 4B.

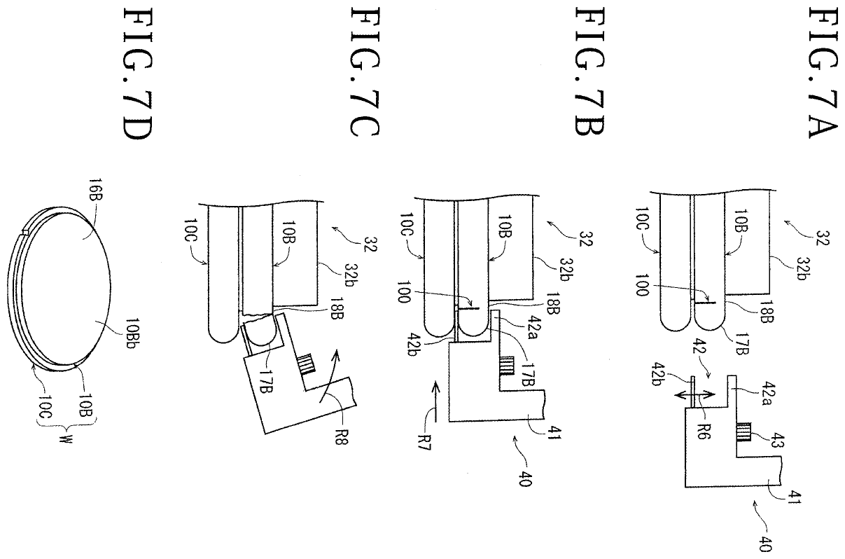

Next, the above-mentioned adjusting valves 37b and 38b are opened, to introduce the high-pressure water L (for example, 0.3 MPa) and the high-pressure air P (for example, 0.6 MPa) from the water source 37 and the air supply source 38 into the fluid jet nozzle 36, and the mixed fluid L+P is jetted from the jet port 36d toward the periphery of the wafer 10A where the chamfer 17A is formed, as depicted in FIG. 5A. Note that, in the embodiment illustrated, the jet port 36d of the fluid jet nozzle 36 is positioned at a position slightly below the back surface 10Ab of the wafer 10A, and is set such that the jetting direction of the mixed fluid L+P jetted is slightly upward with respect to the horizontal direction. As a result, an external force caused by the mixed fluid L+P is exerted on the chamfer 17A at the periphery of the wafer 10A, and the mixed fluid L+P acts in such a manner as to cause the protective tape T and the periphery of the wafer 10A to be separated from each other, whereby the chamfer 17A is broken along the modified layer 100, and the chamfer 17A is removed from the periphery of the wafer 10A, as depicted in FIG. 5B. Note that the part broken in this instance is a region in the vicinity of an area to which the above-mentioned mixed fluid L+P has been jetted.

Then, while the mixed fluid L+P is jetted from the fluid jet nozzle 36 toward the periphery of the wafer 10A as described above, the holding unit 32 is rotated in a direction indicated by an arrow R2 in FIG. 4B, whereby the mixed fluid L+P is jetted over the whole part of the periphery of the wafer 10A, and the chamfer 17A is removed from the effective region 16A over the whole area of the periphery of the wafer 10A, as depicted in FIG. 5C. By the above operations, the chamfer removing step is carried out preferably. Note that the above-described chamfer removing apparatus 30 includes a dedicated closed space for carrying out the chamfer removing step by the holding unit 32 that holds the wafer 10A and the fluid jet nozzle 36, and the chamfer removing step is carried out with the wafer 10A being positioned in the closed space, so that the high-pressure water L jetted from the fluid jet unit 34 and the fragments of the chamfer 17A scattering from the periphery of the wafer 10A can be recovered efficiently. Hence, it is possible to effectively remove the chamfer 17A from the periphery of the wafer 10A, before grinding the back surface 10Ab of the wafer 10A by a grinding apparatus 50 (see FIG. 8) which will be described later; there would be no such problem that the chamfer 17A would stagnate in a drain pan of the grinding apparatus, solving the troublesome problem of necessity for performing frequent cleaning. Note that, in the above-described embodiment, an example in which the chamfer 17A is removed as a start point for removal of the modified layer 100 depicted in FIG. 3A has been described, but it is possible to efficiently remove the chamfer 17A from the effective region 16A of the wafer 10A in a manner similar to the one described above, also by the modified layer or modified layers depicted in FIGS. 3B to 3D.

In the above-described embodiment, the external force to be exerted on the periphery of the wafer 10A has been the mixed fluid L+P formed by mixing the high-pressure air P and the high-pressure water L by the fluid jet nozzle 36 of the fluid jet unit 34, but the present invention is not limited to this; for example, only the high-pressure air P may be jetted to thereby generate the external force for removing the chamfer 17A, or only the high-pressure water L may be jetted to thereby generate the external force for removing the chamfer 17A. In that case, the above-mentioned fluid jet nozzle 36 capable of jetting a binary fluid is not necessarily adopted, and a fluid jet nozzle for jetting a single fluid may be adopted.

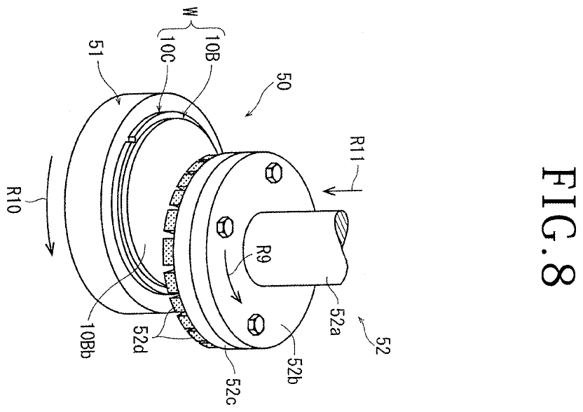

Further, the chamfer removing unit of the present invention is not limited to the chamfer removing unit in which the above-mentioned fluid is used as the external force, and a picker 40 depicted in FIGS. 6 and 7 disposed as a chamfer removing unit in place of the above-described fluid jet unit 34 may be used.

As depicted in FIG. 6, the picker 40 includes a main body part 41 extending in the vertical direction and an external force applying part 42 formed at a lower end part of the main body part 41. The external force applying part 42 includes a fixed plate 42a, a movable plate 42b configured to be adjustable in spacing from the fixed plate 42a, and a spacing adjusting part 43 having a screw structure for moving the movable plate 42b to thereby adjust the spacing between the fixed plate 42a and the movable plate 42b. The picker 40 is supported by the chamfer removing apparatus 30 through an unillustrated moving mechanism, and is configured such that the picker 40 can be lifted and lowered in a direction indicated by an arrow R3 and can be moved in a direction (horizontal direction) indicated by an arrow R4 in the figure, that is, toward the holding unit 32. In addition, the picker 40 is configured such that the external force applying part 42 of the picker 40 is inclined by the main body part 41 being inclined in a direction indicated by an arrow R5 in the figure where the holding unit 32 is positioned.

The above-mentioned picker 40 is preferable in the case of removing the chamfer 17B of the first wafer 10B of the bonded wafer W formed by bonding the first wafer 10B with the second wafer 10C as has been described with reference to FIG. 1B. Hence, in the following description, a description will be given of a mode of carrying out the chamfer removing step on the bonded wafer W that has been formed with the modified layer 100 along the chamfer 17B in the inside of the boundary part 18B between the effective region 16B and the chamfer 17B of the first wafer 10B of the bonded wafer W formed by bonding the first wafer 10B with the second wafer 10C, in the above-described modified layer forming step.

When the modified layer forming step has been carried out on the first wafer 10B of the bonded wafer W, the effective region 16B of the first wafer 10B constituting the bonded wafer W is held by the holding unit 32, by a procedure similar to the procedure that has been described with reference to FIG. 4A, and an unillustrated moving mechanism is operated to thereby position the holding unit 32 in the vicinity of the external force applying part 42 of the picker 40, as depicted in FIG. 6.

Next, by the above-mentioned spacing adjusting part 43 being rotated, the movable plate 42b is adjusted in a direction indicated by an arrow R6 as depicted in FIG. 7A, such that the spacing between the fixed plate 42a and the movable plate 42b are adjusted to such a spacing as to be able to accept the thickness of the periphery of the first wafer 10B and the movable plate 42b is positioned at the height of a boundary at which the first wafer 10B and the second wafer 10C are bonded with each other. Next, as depicted in FIG. 7B, an unillustrated moving mechanism is operated to thereby move the picker 40 in a direction indicated by an arrow R7, whereby the movable plate 42b is inserted into the boundary at which the first wafer 10B and the second wafer 10C are bonded with each other. When the movable plate 42b has been inserted as described above, the main body part 41 is inclined in a direction indicated by an arrow R8, as depicted in FIG. 7C. As a result, the movable plate 42b acts on the periphery including the chamfer 17B of the first wafer 10B, to thereby break the chamfer 17B along the above-mentioned boundary part 18B. Since the breakage occurs only in the region where the movable plate 42b has been inserted and the vicinity thereof, the picker 40 is temporarily separated from the first wafer 10B, and the main body part 41 is returned into a vertical state, that is, into the state depicted in FIG. 7A.

The fragments of the chamfer 17B broken formerly drop off from the picker 40 during this operation. Next, the holding unit 32 is rotated in a direction indicated by the arrow R2 in FIG. 6 by a predetermined angle, whereby the periphery where the unbroken chamfer 17B remains is positioned in the vicinity of the external force applying part 42 of the picker 40. Then, the above-described operations depicted in FIGS. 7B and 7C are carried out again, to thereby remove the chamfer 17B from the periphery. These operations are repeated a plurality of times, whereby there is obtained a bonded wafer W with the chamfer 17B having been removed from the above-mentioned effective region 16B over the whole range of the periphery of the first wafer 10B, as depicted in FIG. 7D, and the chamfer removing step is completed.

Note that, in the above-described embodiment, an example in which the chamfer 17A of a simple wafer 10A is removed by use of the fluid jet unit 34 for jetting fluid and an example in which the chamfer 17B of the first wafer 10B of the bonded wafer W formed by bonding the first wafer 10B and the second wafer 10C with each other is removed by use of the picker 40 have been described, but the present invention is not limited to these configurations. For example, the chamfer 17B of the first wafer 10B of the bonded wafer W formed by bonding the first wafer 10B and the second wafer 10C may be removed by use of the above-mentioned fluid jet unit 34, or the chamfer 17A of the simple wafer 10A may be removed by use of the picker 40.

When the above-described chamfer removing step has been completed, a processing step is carried out in which the back surface of the wafer is ground to process the wafer to a desired thickness. The wafer to be processed is a wafer having been subjected to the chamfer removing step. In the following description, a mode in which the processing step of grinding the back surface 10Bb of the bonded wafer W including the first wafer 10B with the chamfer 17B having been removed by the above-described chamfer removing step and processing the bonded wafer W to a desired thickness is performed will be described.

The bonded wafer W having been subjected to the chamfer removing step is conveyed to the grinding apparatus 50 depicted in FIG. 8 (only a part thereof is depicted). As illustrated in the figure, the grinding apparatus 50 includes a grinding unit 52 for grinding the back surface 10Bb of the first wafer 10B of the bonded wafer W held on the chuck table 51 under suction and thinning the bonded wafer W. The grinding unit 52 includes a rotary spindle 52a rotated by an unillustrated rotational drive source, a wheel mount 52b mounted to a lower end of the rotary spindle 52a, and a grinding wheel 52c mounted to a lower surface of the wheel mount 52b, with a plurality of grindstones 52d arranged in an annular pattern on a lower surface of the grinding wheel 52c.

When the bonded wafer W has been conveyed to the grinding apparatus 50 and mounted on the chuck table 51 with the second wafer 10C side directed downward and unillustrated suction means is operated to hold the bonded wafer W under suction, the rotary spindle 52a of the grinding unit 52 is rotated in a direction indicated by an arrow R9 in FIG. 8 at, for example, 6,000 rpm, and, simultaneously, the chuck table 51 is rotated in a direction indicated by an arrow R10 at, for example, 300 rpm. Then, while grinding water is supplied onto the back surface 10Bb of the first wafer 10B by an unillustrated grinding water supply unit, the grindstones 52d are brought into contact with the back surface 10Bb of the first wafer 10B, and the griding wheel 52c is brought into griding feed in a downward direction indicated by an arrow R11 at a grinding feed rate of, for example, 1 μm/s. In this instance, the grinding can be proceeded while the thickness of the bonded wafer W is measured by an unillustrated contact type or non-contact type measuring gauge, and, when the back surface 10Bb of the first wafer 10B has been ground by a predetermined amount to thin the bonded wafer W to a desired thickness, the grinding unit 52 is stopped, and the processing step is completed. When the above-described processing step has been completed, cleaning and drying steps and the like of which the details are omitted are carried out as required. In the above-described processing step, the mode in which the back surface 10Bb of the first wafer 10B of the bonded wafer W formed by bonding the first wafer 10B and the second wafer 10C with each other is ground to thereby process the bonded wafer W to a desired thickness has been described, but, also in the case of grinding the back surface 10Ab of the wafer 10A described above to thereby process the wafer 10A to a desired thickness, the processing can be performed by a similar procedure by use of the above-mentioned grinding apparatus 50. By the above operations, the wafer processing method of the present embodiment is completed.

According to the processing method of the embodiment described above, it is possible to effectively remove the chamfer from the periphery of the wafer before the back surface of the wafer is ground to process the wafer to a desired thickness, so that there would be no such problem that the chamfer would stagnate in the drain pan of the grinding apparatus for carrying out the processing step, solving the troublesome problem of the necessity for frequent cleaning of the drain pan of the grinding apparatus.

In addition, in the case where the chamfer removing step in the processing method of the present embodiment is carried out by use of the above-mentioned chamfer removing apparatus 30, it is possible to effectively remove the chamfer from the periphery of the wafer before the wafer is ground by the processing step of grinding the back surface of the wafer to process the wafer to a desired thickness, so that there would be no such problem that the chamfer would stagnate in the drain pan of the grinding apparatus for carrying out the processing step, solving the troublesome problem of the necessity for frequent cleaning of the drain pan.

In the above-described embodiment, an example in which the above-mentioned chamfer removing apparatus 30 is juxtaposed to the laser processing apparatus 20 has been described, but the present invention is not limited to this configuration, and an independent chamfer removing apparatus 30 may be disposed separately from the laser processing apparatus 20. In that case, it is sufficient that, after the modified layer forming step is carried out in the laser processing apparatus 20, the wafer conveyed out from the laser processing apparatus 20 is conveyed into the chamfer removing apparatus 30, is thereafter held by the holding unit 32, and is subjected to the above-described chamfer removing step.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A wafer processing method for processing a wafer that has an effective region and a chamfer at an end part of a periphery surrounding the effective region, the wafer processing method comprising:
a modified layer forming step of applying a laser beam of such a wavelength as to be transmitted through the wafer to the wafer, with a focal point of the laser beam positioned in inside of a boundary part between the effective region and the chamfer, to thereby form a modified layer along the chamfer;
a chamfer removing step of holding the effective region of the wafer and exerting an external force on the periphery of the wafer to thereby remove the chamfer; and
a processing step of grinding a back surface of the wafer from which the chamfer has been removed, to thereby process the wafer to a desired thickness.

2. The wafer processing method according to claim 1, wherein the external force exerted on the periphery of the wafer in the chamfer removing step is any of high-pressure air, high-pressure water, a mixed fluid of high-pressure air and high-pressure water, and a picker.

3. The wafer processing method according to claim 1,
wherein the wafer is a bonded wafer in which a first wafer and a second wafer are bonded with each other, and
the modified layer forming step, the chamfer removing step, and the processing step are carried out on the first wafer.

4. A chamfer removing apparatus for removing a chamfer from a wafer which has an effective region and the chamfer at an end part of a periphery surrounding the effective region and in which a modified layer has been formed along the chamfer, the chamfer removing apparatus comprising:
a holding unit that has a holding surface for holding the effective region of the wafer; and
a chamfer removing unit that exerts an external force on the periphery of the wafer held by the holding unit, the periphery projecting outward from the holding surface, to thereby remove the chamfer from the effective region.

5. The chamfer removing apparatus according to claim 4, wherein the chamfer removing unit is means for exerting an external force on the periphery of the wafer by any of high-pressure air, high-pressure water, a mixed fluid of high-pressure air and high-pressure water, and a picker.
